(19) United States
(12) Patent Application Publication
(10) Pub. No.: US 2025/0142723 A1
(43) Pub. Date: May 1, 2025

(54) LIGHTING DEVICE

(71) Applicant: LITE-ON TECHNOLOGY CORPORATION, TAIPEI CITY (TW)

(72) Inventor: SHAN-HUI CHEN, Taoyuan City (TW)

(21) Appl. No.: 18/923,641

(22) Filed: Oct. 22, 2024

Related U.S. Application Data
(60) Provisional application No. 63/545,716, filed on Oct. 25, 2023.

(30) Foreign Application Priority Data
Sep. 23, 2024 (CN) 202422315688.4

(51) Int. Cl. H05K 1/11; H05K 1/18

(52) U.S. Cl. CPC H05K 1/113; H05K 1/115; H05K 1/181; H05K 2201/09427; H05K 2201/10106

(57) ABSTRACT

A lighting device includes a carrier, a plurality of configuration pads, a plurality of light emitting diode chips, an integrated circuit chip, five external pads, and a connection component. The carrier includes a first substrate, a second substrate, and a third substrate. The second substrate is located between the first substrate and the third substrate. The configuration pads are disposed on the first substrate and are spaced apart from each other. The light emitting diode chips and the integrated circuit chips are electrically connected to the configuration pads. The five external pads are disposed on the third substrate and are spaced apart from each other. A portion of the connection component passes through the first substrate and the third substrate, so as to be electrically coupled to the configuration pads and the five external pads.

### CROSS-REFERENCE TO RELATED PATENT APPLICATION

This application claims the benefit of priority to the U.S. Provisional Patent Application Ser. No. 63/545,716, filed on Oct. 25, 2023, and China Patent Application No. 202422315688.4, filed on Sep. 23, 2024, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a device, and more particularly to a lighting device.

### BACKGROUND OF THE DISCLOSURE

Referring to FIG. 21 and FIG. 22, a conventional lighting device X200 includes a carrier X210, an integrated circuit chip X220 and a plurality of light emitting diode chips X230 disposed on the carrier X210, and four pads X240A and X240B that are located at a bottom of the carrier X210. The power supply voltage of the integrated circuit chip X220 and anodes of the light emitting diode chips X230 are jointly connected to one of the pads X240A, and three other pads X240B are connected to an input electrode, an output electrode, and a ground terminal of the integrated circuit chip X220.

However, due to the design of the four pads X240A and X240B in the conventional lighting device X200, the input power supply voltage (VDD) of the integrated circuit chip X220 and the anodes of the light emitting diode chips X230 are commonly connected to the same pad X240A. This design further prevents functional tests from being performed on the integrated circuit chip X220 of the conventional lighting device X200 prior to installation on the printed circuit board.

### SUMMARY OF THE DISCLOSURE

In response to the above-referenced technical inadequacy, the present disclosure provides a lighting device.

In order to solve the above-mentioned problems, one of the technical aspects adopted by the present disclosure is to provide a lighting device. The lighting device includes a carrier, a plurality of configuration pads, a plurality of light emitting diode chips, five external pads, and a connection component. The carrier includes a first substrate, a second substrate, and a third substrate. The second substrate is located between the first substrate and the third substrate. The configuration pads are disposed on the first substrate. The configuration pads are spaced apart from each other. The light emitting diode chips and the integrated circuit chip are electrically connected to the configuration pads. The five external pads are disposed on the third substrate. The five external pads are spaced apart from each other. The connection component is disposed on the second substrate. A portion of the connection component passes through the first substrate and the third substrate, so as to be electrically coupled to the configuration pads and the five external pads.

Therefore, in the lighting device provided by the present disclosure, by virtue of “the five external pads being spaced apart from each other,” and “a portion of the connection component passing through the first substrate and the third substrate, so as to be electrically coupled to the configuration pads and the five external pads,” the lighting device can perform functional testing on the integrated circuit chip before being installed on the circuit substrate.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic circuit diagram of a lighting device according to the present disclosure;

FIG. 2 is a schematic plan view of a first substrate of the lighting device according to the present disclosure;

FIG. 3 is a schematic plan view of a second substrate of the lighting device according to the present disclosure;

FIG. 4 is a schematic plan view of a third substrate of the lighting device according to the present disclosure;

FIG. 5 is a schematic plan view of the first substrate of the lighting device according to the present disclosure in another implementation;

FIG. 6 is a schematic plan view of the second substrate of the lighting device of FIG. 5;

FIG. 7 is a schematic plan view of the third substrate of the lighting device of FIG. 5;

FIG. 8 is another schematic circuit diagram of the lighting device according to the present disclosure;

FIG. 9 is a schematic plan view of the first substrate of the lighting device according to the present disclosure in yet another implementation;

FIG. 10 is a schematic plan view of the second substrate of the lighting device of FIG. 9;

FIG. 11 is a schematic plan view of the third substrate of the lighting device of FIG. 9;

FIG. 12 is a schematic plan view of the first substrate of the lighting device according to the present disclosure in still another implementation;

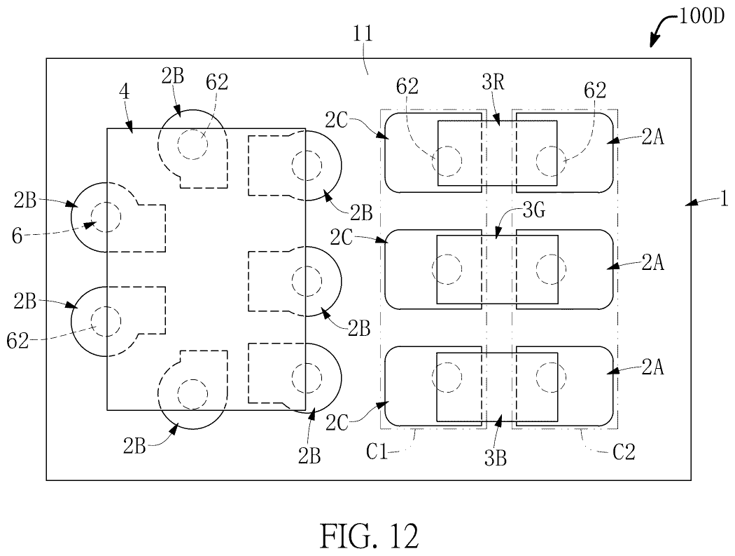

FIG. 13 is a schematic plan view of the second substrate of the lighting device of FIG. 12;

FIG. 14 is a schematic plan view of the third substrate of the lighting device of FIG. 12;

FIG. 15 is a schematic plan view of the first substrate of the lighting device according to the present disclosure in still another implementation;

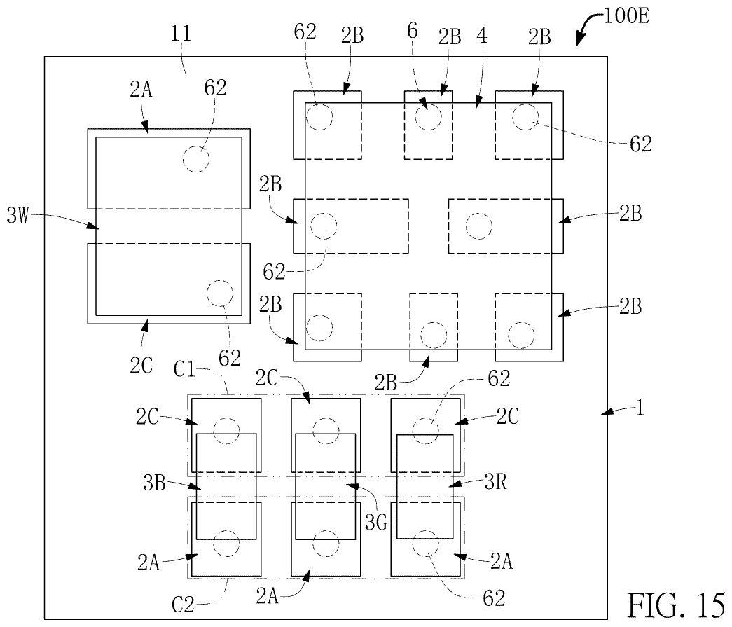

FIG. 16 is a schematic plan view of the second substrate of the lighting device of FIG. 15;

FIG. 17 is a schematic plan view of the third substrate of the lighting device of FIG. 15;

FIG. 18 is a schematic plan view of the first substrate of the lighting device according to the present disclosure in still another implementation;

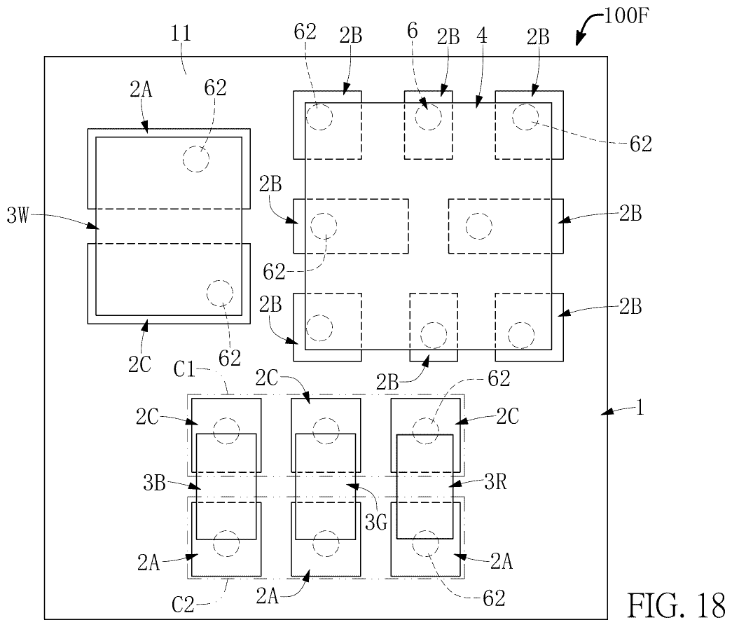

FIG. 19 is a schematic plan view of the second substrate of the lighting device of FIG. 18;

FIG. 20 is a schematic plan view of the third substrate of the lighting device of FIG. 18;

FIG. 21 is a schematic perspective view of a conventional lighting device; and

FIG. 22 is another schematic perspective view of the conventional lighting device.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

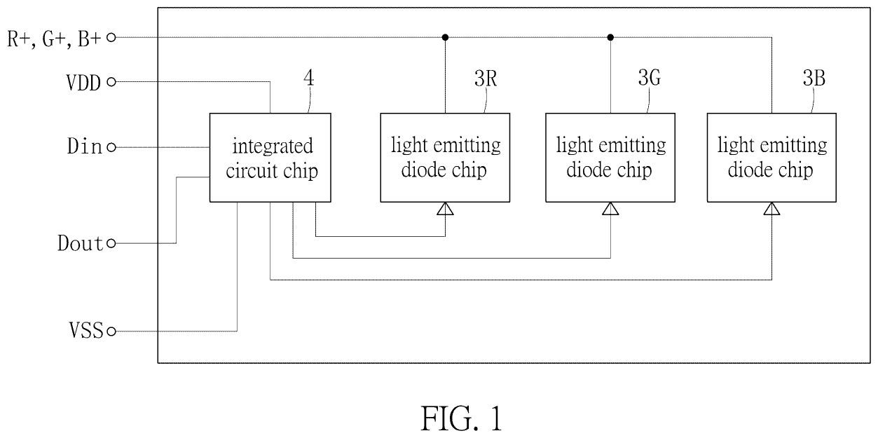

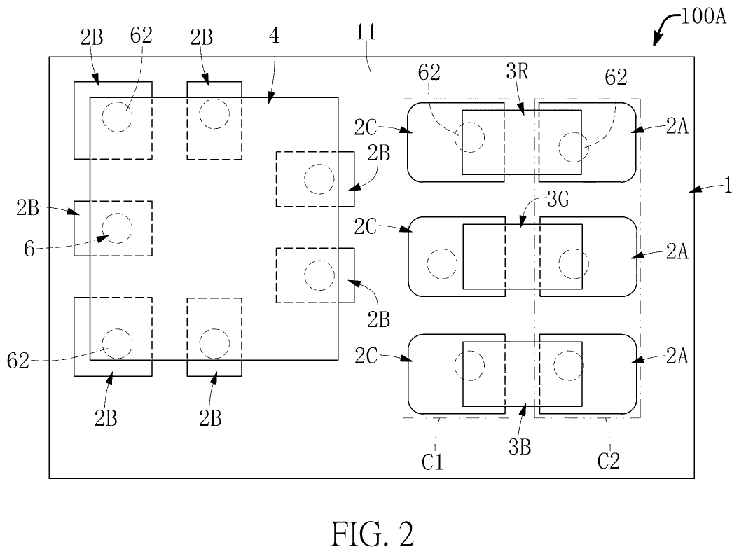

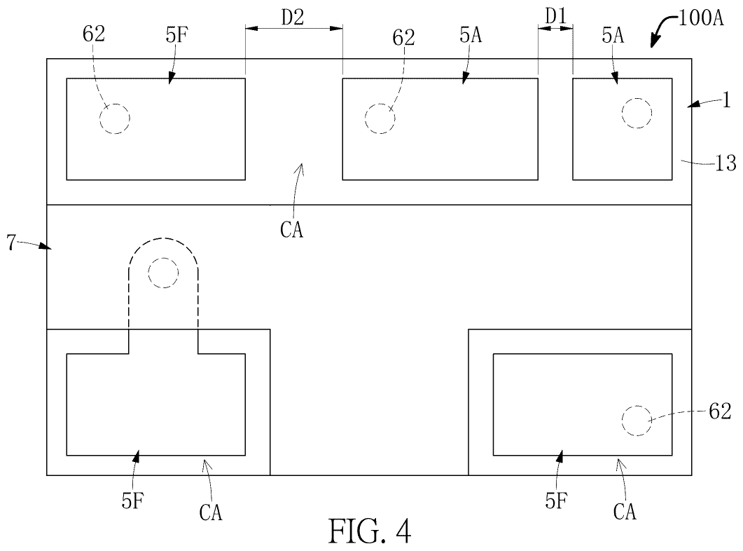

Referring to FIG. 1 to FIG. 4, an embodiment of the present disclosure provides a lighting device 100A, the lighting device 100A includes a carrier 1, a plurality of configuration pads (i.e., 2A, 2B and 2C shown in FIG. 2), a plurality of light emitting diode chips 3R, 3G, and 3B, an integrated circuit chip 4, five external pads (i.e., 5A and 5F shown in FIG. 4), and a connection component 6. Before the lighting device 100A is mounted on a circuit substrate (not shown), the lighting device 100A can individually detect the integrated circuit chip 4 through a power supply voltage VDD, a data input electrode Din, data output electrode Dout, and a ground electrode VSS (as detailed later), based on the configuration of five external pads, to ensure the reliability of the lighting device 100A.

Before explaining the lighting device 100A, it is necessary to first clarify that in the present embodiment, the lighting device 100A is described using a flip-chip structure. That is, the integrated circuit chip 4 and the configuration pads are fixed and electrically connected using the flip-chip method; however, the present disclosure is not limited thereto. The following description describes the structure and connection relation of each component of the lighting device 100A.

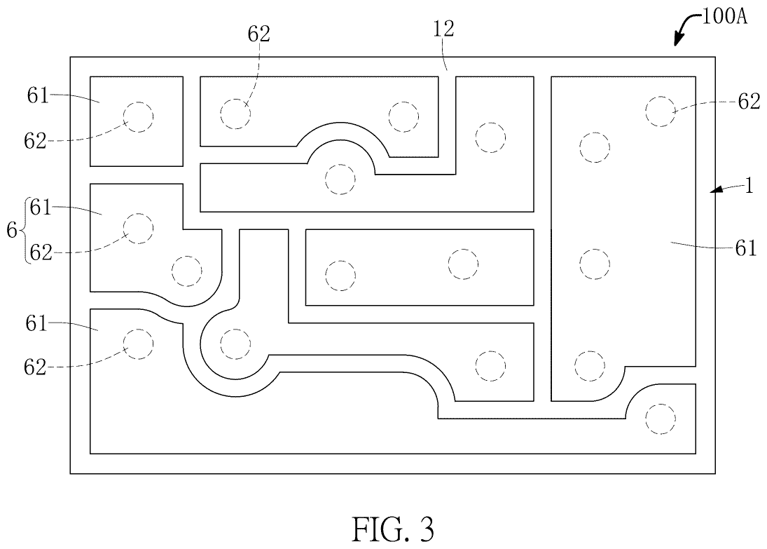

Referring to FIG. 2 to FIG. 4, in the present embodiment, the carrier 1 is a multi-layer board structure, and the carrier 1 includes a first substrate 11, a second substrate 12, and a third substrate 13. The carrier 1 has a thickness direction (not shown), the first substrate 11, the second substrate 12, and the third substrate 13 are stacked sequentially along the thickness direction, so that the second substrate 12 is located between the first substrate 11 and the third substrate 13. In order to facilitate understanding, FIG. 2 and FIG. 3 are illustrated from a top view of the carrier 1, and FIG. 4 is illustrated from a bottom view of the carrier 1.

Referring to FIG. 2, the configuration pads (i.e., 2A, 2B and 2C shown in FIG. 2) in the present embodiment are made of conductive metal materials. The configuration pads are disposed on a side surface of the first substrate 11 away from the second substrate 12, and the configuration pads are spaced apart from each other. In other words, the configuration pads are exposed on a surface of the carrier 1.

In practice, a plurality of sides of the configuration pads and a plurality of sides of the first substrate 11 can be spaced apart from each other. That is to say, each of the configuration pad does not extend to the sides of the first substrate 11, so that each of the configuration pad does not form a sidewall conductive member on the sides of the carrier 1.

Referring to FIG. 2, the light emitting diode chips 3R, 3G, 3B and the integrated circuit chip 4 are disposed on the side surface of the first substrate 11 away from the second substrate 12. The light emitting diode chips 3R, 3G, 3B and the integrated circuit chip 4 are electrically connected to the configuration pads.

In practice, as shown in FIG. 1 and FIG. 2, the light emitting diode chips 3R, 3G, and 3B have anode terminals R+, G+, B+ respectively. Each of the light emitting diode chips 3R, 3G, 3B has a cathode terminal (not labeled in the drawings). Each of the anode terminals R+, G+, B+ and cathode terminal is electrically connected to one of the configuration pads. One of the configuration pads electrically connected to anyone of the anode terminals R+, G+, and B+ is defined as anode pad 2A, and one of the configuration pads electrically connected to the cathode terminal is defined as a cathode pad 2C. The anode pads 2A and the cathode pads 2C may be arranged in a matrix (e.g., a 6×2 matrix). That is to say, a portion of the configuration pads is arranged in a matrix.

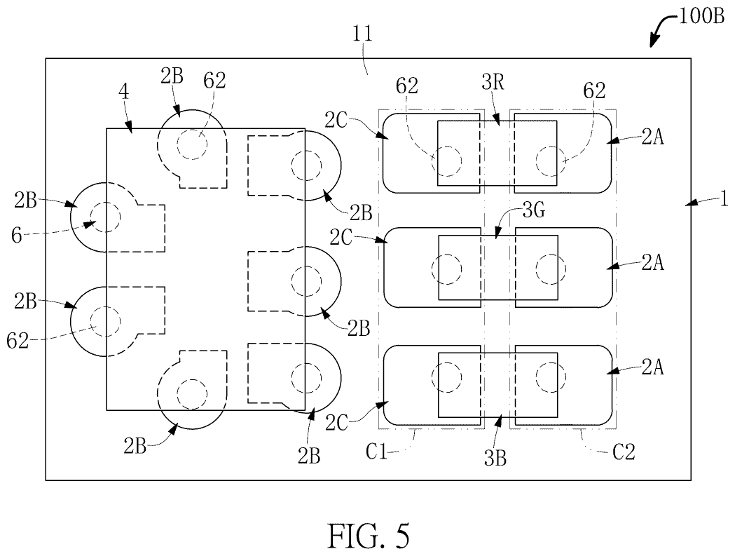

The cathode pads 2C may be arranged in a first column C1, and the anode pads 2A may be arranged in a second column C2 parallel to the first column C1. In other words, the electrodes of the configuration pads located in the first column C1 are anodes, and the electrodes of the configuration pads located in the second column C2 are cathodes (as shown in FIG. 2 and FIG. 5), but the present disclosure is not limited thereto.

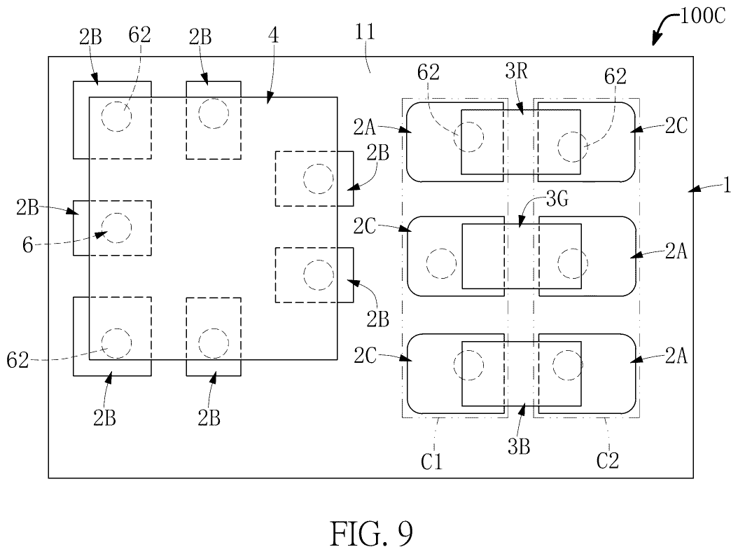

For example, with reference to the lighting device 100C in FIG. 9 to FIG. 11, the first column C1 and the second column C2 can each have at least one of the anode pads 2A and at least one of the cathode pads 2C. In other words, the electrodes of the configuration pads located in the first column C1 include both anodes and cathodes, and the electrodes of the configuration pads located in the second column C2 also include both anodes and cathodes (as shown in FIG. 9).

In addition, another part of the configuration pads can be defined as chip pads 2B, and the chip pads 2B can be substantially covered by the integrated circuit chip 4 and electrically connected to the integrated circuit chip 4.

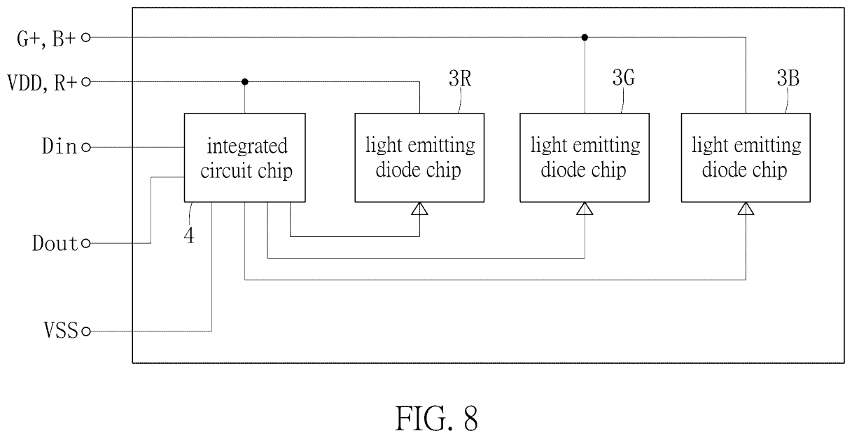

Referring to FIG. 1 and FIG. 8 (FIG. 1 is a schematic circuit diagram of the lighting devices 100A, 100B, and FIG. 8 is a schematic circuit diagram of the lighting devices 100C, 100D), the integrated circuit chip 4 has an input power supply voltage VDD, a data input electrode Din, a data output electrode Dout, and a ground electrode VSS. The input power supply voltage VDD provides an operating voltage required by the integrated circuit chip 4. The ground electrode VSS serves as a zero potential reference point of the integrated circuit chip 4. The data input electrode Din is used to input an external signal to the light emitting diode chips 3R, 3G, and 3B for control. The data output electrode Dout can connect signals to another lighting device in series.

Referring to FIG. 4, the five external pads in the present embodiment are made of conductive metal material and are disposed on a side surface of the third substrate 13 away from the second substrate 12. The external pads are arranged spaced apart from each other. In other words, the external pads are also exposed on the surface of the carrier 1, and the lighting device can be electrically connected to other devices or components through the five external pads.

For the convenience of subsequent explanation, the five external pads are defined as two anode external pads 5A and three function external pads 5F. Each of the two anode external pads 5A can be understood as an external pad that is electrically coupled to any one of the anode pads 2A or the input power supply voltage VDD (i.e., with the electrode being positive). Each of the three function external pads 5F can be understood as an external pad that is electrically coupled to any of the data input electrode, the data output electrode, or the ground electrode.

In one embodiment, one of the two anode external pads 5A is electrically coupled to the input power supply voltage VDD of the integrated circuit chip 4, and another one of the two anode external pads 5A is electrically coupled to the anode terminals R+, G+, B+ of the light emitting diode chips 3R, 3G, 3B, but the present disclosure is not limited thereto.

In another one embodiment, one of the two anode external pads 5A is electrically coupled to the input supply voltage VDD of the integrated circuit chip 4 and the anode terminal R+ of one of the light emitting diode chips 3R, and another one of the two anode external pads 5A is electrically coupled to each of the anode terminals G+, B+ of a remaining of the light emitting diode chips 3G, 3B.

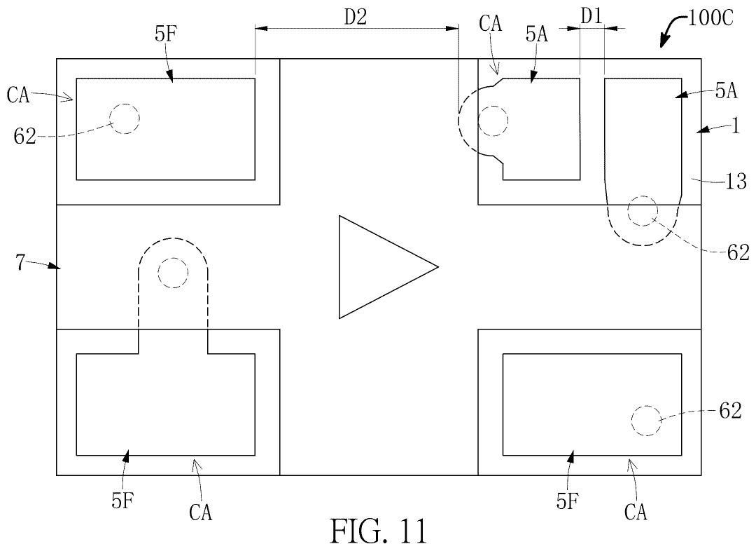

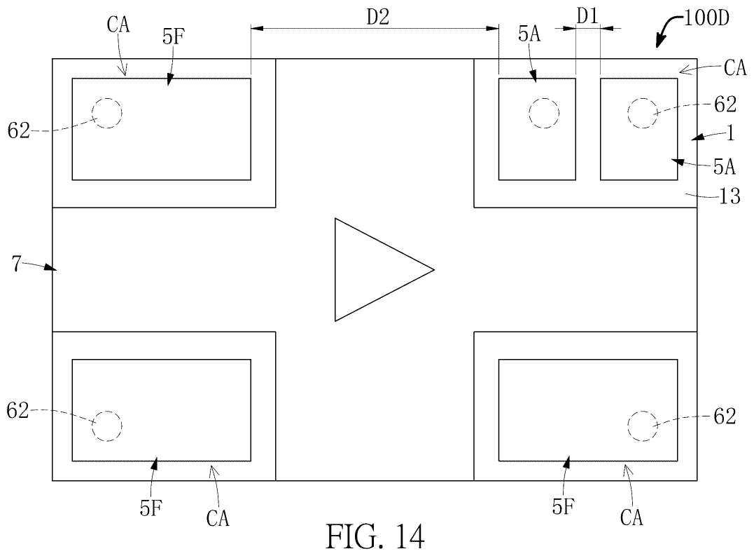

That is to say, one of the light emitting diode chips 3R and the integrated circuit chip 4 are jointly connected to the same external pad (e.g., the lighting devices 100C and 100D as shown in FIG. 11 and FIG. 14).

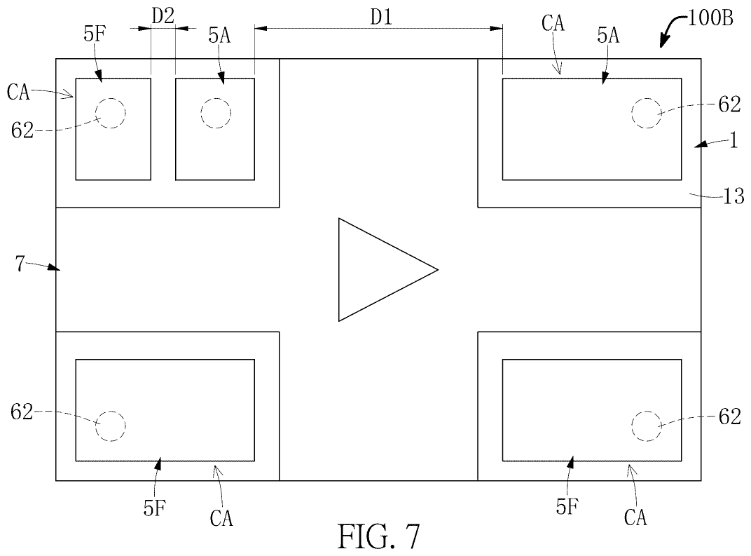

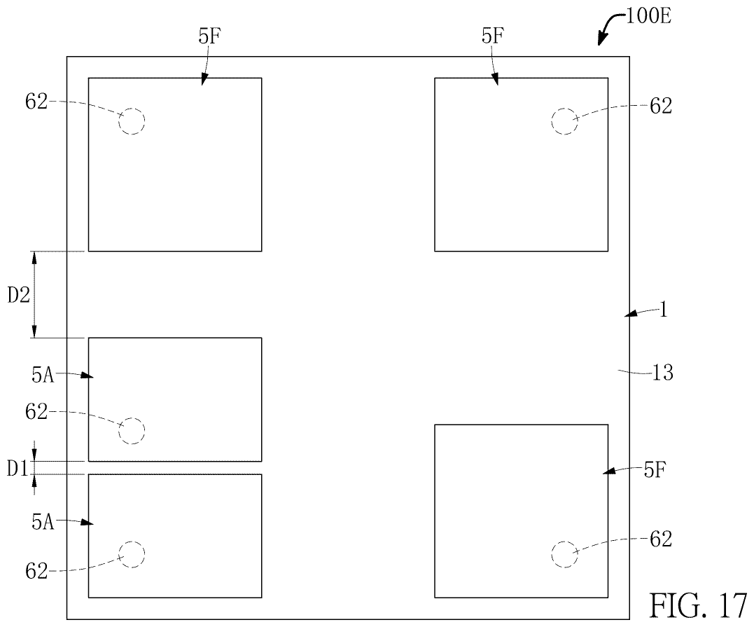

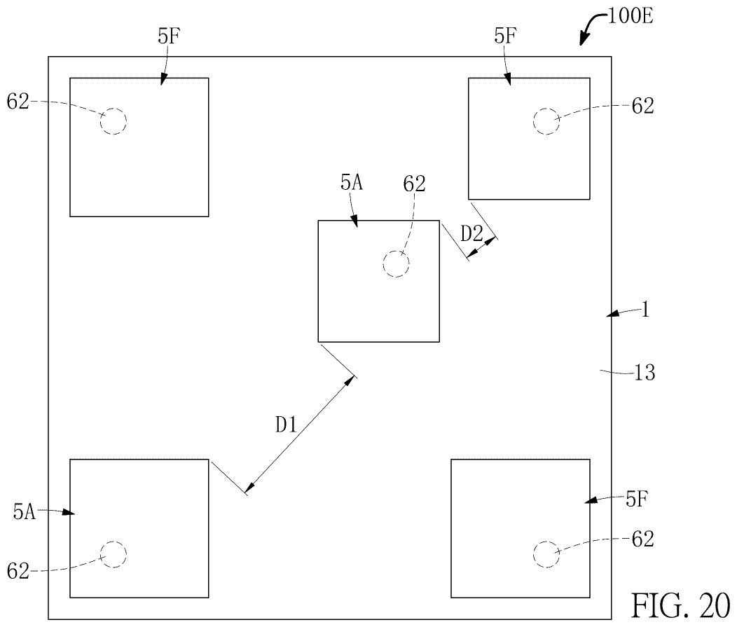

Preferably, the two anode external pads 5A can be designed to be arranged adjacent to each other. Specifically, as shown in FIG. 4, FIG. 11, FIG. 14, and FIG. 17, a first shortest distance D1 is between the two anode external pads 5A, a second shortest distance D2 is between any one of the two anode external pads 5A and any one of the three function external pads 5F, and the first shortest distance D1 is less than the second shortest distance D2, but the present disclosure is not limited thereto. For example, as shown in FIG. 7 and FIG. 20, the first shortest distance D1 may also be designed to be greater than the second shortest distance D2 according to practical requirements.

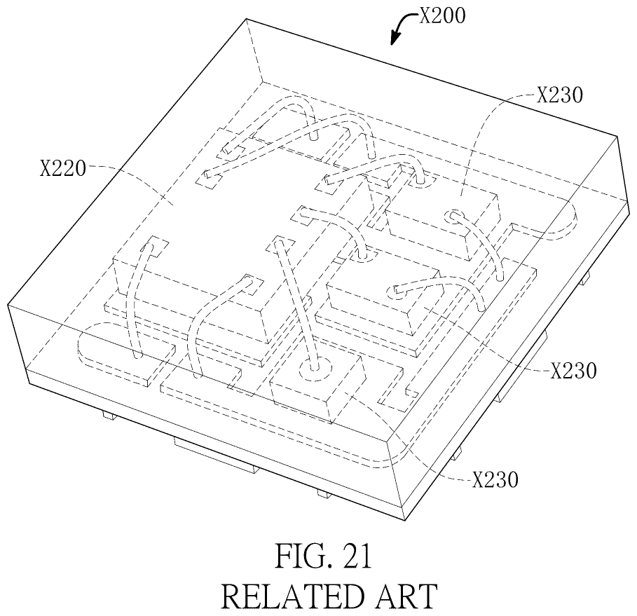

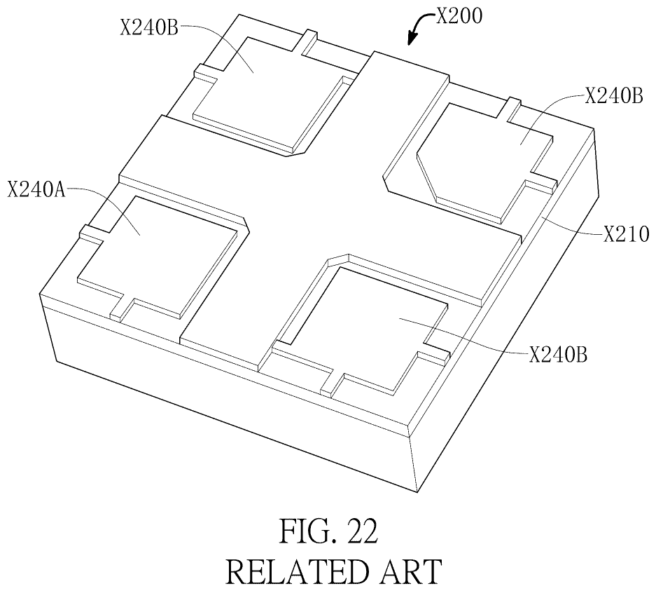

It should be noted that the conventional lighting device X200 uses four pads X240A, X240B (as shown in FIG. 21 and FIG. 22), and the power supply voltage of the integrated circuit chip X220 and the anodes of the light emitting diode chips X230 are jointly connected to one of the four pads X240A. The other three pads X240B are used to be connected to the data input electrode, the data output electrode, and the ground terminal (GND) of the integrated circuit chip X220. Therefore, the circuit of the printed circuit board currently on the market are also designed to match four configuration pads X240A, X240B.

For this reason, by virtue of “the first shortest distance D1 being smaller than the second shortest distance D2,” the two anode external pads 5A can directly match the printed circuit board on the market. In other words, customers can install the lighting device of the present disclosure without additional changes to the circuit of the printed circuit board.

Referring to FIG. 3, the connection component 6 is disposed on the second substrate 12, a portion of the connection component 6 passes through the first substrate 11 and the third substrate 13 to electrically couple the configuration pads and the five external pads. In other words, the light emitting diode chips 3R, 3G, 3B and the integrated circuit chip 4 located on the first substrate 11 can be connected to the five external pads located on the third substrate 13 through the connection component 6.

In practice, the connection component 6 includes an M+5 number of connection conduction pads 61 and a plurality of conductive pillars 62. The quantity of the light emitting diode chips is M, and M is a positive integer greater than or equal to three. In other words, a corresponding relationship can be between the quantity of the M+5 connection conduction pads 61 of the connection component 6 and the quantity of the light emitting diode chips.

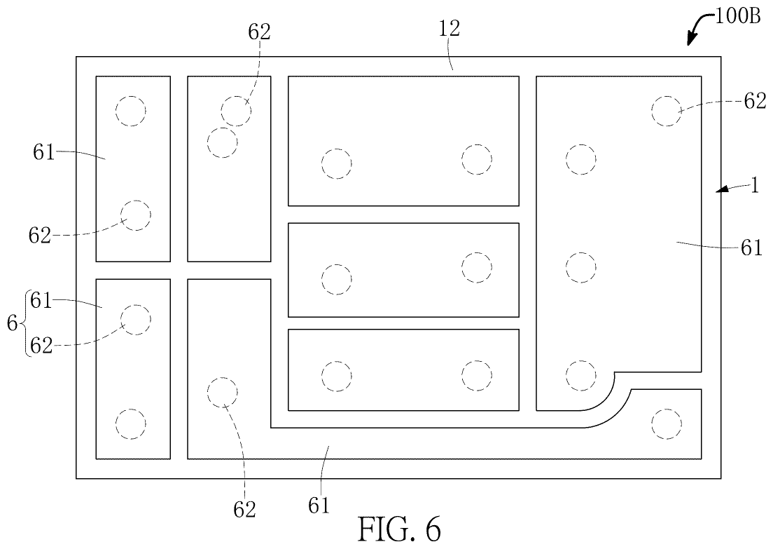

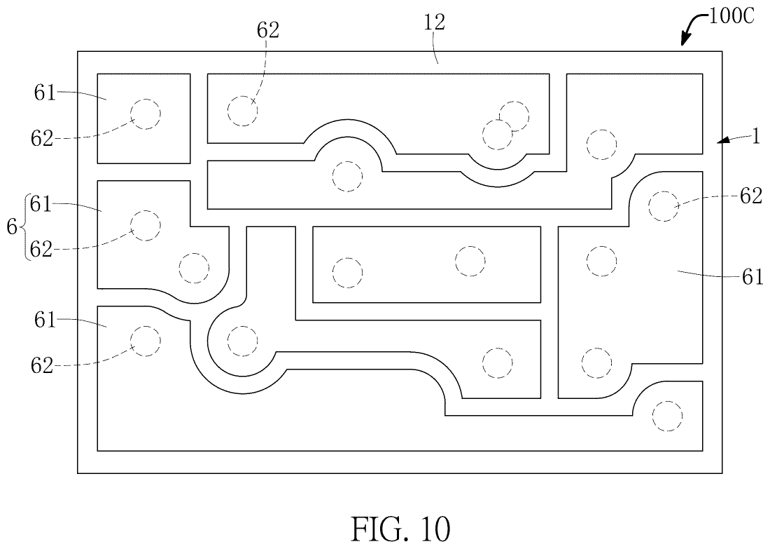

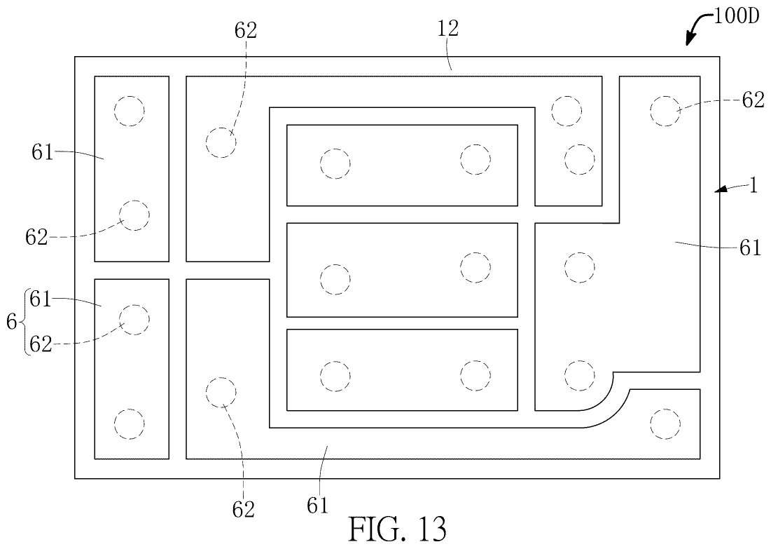

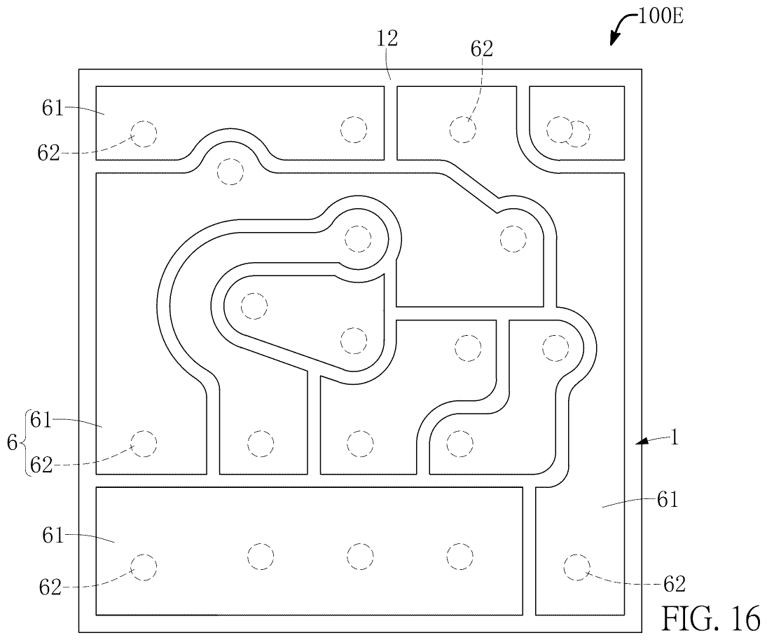

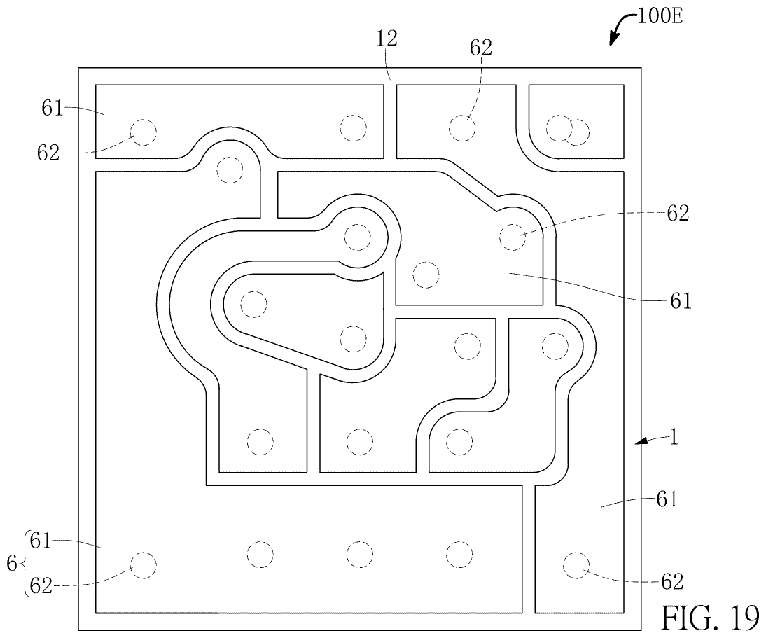

For example, when the lighting device (e.g., the lighting devices 100A, 100B, 100C, 100D) has three light emitting diode chips 3R, 3G, 3B for red, blue, and green light (i.e., M equals 3), the connection component 6 has eight connection conduction pads 61 (as shown in FIG. 3, FIG. 6, FIG. 10, and FIG. 13). As another example, when the lighting device (e.g., the lighting devices 100E, 100F) has four light-emitting diode chips 3R, 3G, 3B, 3W for white, red, blue, and green light (i.e., M equals 4), the connection component 6 has nine connection conduction pads 61 (as shown in FIG. 16 and FIG. 19).

Furthermore, the M+5 connection conduction pads 61 are disposed on the second substrate 12, and the M+5 connection conduction pads 61 are spaced apart from each other. In the present embodiment, each of the M+5 connection conduction pads 61 is rectangular and L-shaped, and the M+5 connection conduction pads 61 roughly occupy a side surface of the second substrate 12. Preferably, a total area of the M+5 connection conduction pads 61 may be greater than or equal to 50% of a total area of the side surface of the second substrate 12.

In addition, the conductive pillars 62 pass through the first substrate 11 and the second substrate 12, a subset of the conductive pillars 62 are electrically coupled to the configuration pads and the M+5 connection conduction pads 61, and another subset of the conductive pillars 62 are electrically coupled to the five external pads and the M+5 connection conduction pads 61.

It is worth noting that, as shown in FIG. 4, the lighting device 100A may also optionally include a solder resist coating 7 disposed on the third substrate 13, the solder resist coating 7 separates a plurality of configuration regions CA on the third substrate 13, and at least one of the five external pads is disposed in one of the configuration regions CA. It can also be understood that the solder resist coating 7 separates the five external pads to reduce mutual influence between the five external pads.

In one embodiment, as shown in FIG. 4, the solder resist coating 7 is roughly T-shaped, so that a quantity of the configuration regions CA is three. The two anode external pads 5A and one of the three function external pads 5F are disposed in one of the three configuration regions CA. The first shortest distance D1 between the two anode external pads 5A is less than the second shortest distance D2 between any one of the two anode external pads 5A and any one of the three function external pads 5F.

In another embodiment, as shown in FIG. 11 and FIG. 14, the solder resist coating 7 is roughly in the shape of a cross, so that a quantity of configuration regions CA is four. The two anode external pads 5A are disposed in one of the four configuration regions CA, and the three functions external pads 5F are respectively disposed in another three of the four configuration regions CA. The first shortest distance D1 between the two anode external pads 5A is less than the second shortest distance D2 between any one of the two anode external pads 5A and any one of the three function external pads 5F.

In yet another embodiment, as shown in FIG. 7, the solder resist coating 7 is roughly in the shape of a cross, so that a quantity of configuration regions CA is four. One of the two anode external pads 5A corresponding to the input power supply voltage VDD and one of the three function external pad 5F are disposed in one of the four configuration regions CA. One of the two anode external pads 5A corresponding to the anode terminals of the light emitting diode chips and another one of the three function external pads 5F are disposed in another one of the four configuration regions CA. A remaining two of the three functions external pads 5F are respectively disposed in another two of the four configuration regions CA. That is to say, the two anode external pads 5A corresponding to the input power supply voltage VDD and one of the three function external pads 5F are adjacent to each other.

In summary, to facilitate understanding of the technical effects of the lighting device in the present disclosure, the following explanation will use the lighting device 100A, as shown in FIG. 2 to FIG. 4, as an example. One of the two anode external pads 5A located on a left side of FIG. 4 is electrically coupled via the connection component 6 to the anode pads 2A of the three light-emitting diode chips 3R, 3G, 3B, and one of the two anode external pads 5A in a middle position of FIG. 4 is electrically coupled to the input power supply voltage VDD of the integrated circuit chip 4 via the connection component 6. That is to say, a circuit of the integrated circuit chip 4 and circuits of the three light emitting diode chips 3R, 3G, 3B have been separated and do not share the same external pad (as shown in FIG. 1).

Accordingly, by virtue of “the circuit of the integrated circuit chip 4 and the circuits of the three light emitting diode chips 3R, 3G, 3B,” the lighting device in the present disclosure can perform individual functional testing on the integrated circuit chip 4 before being installed on the circuit substrate. Similarly, the lighting devices in other embodiments of this present disclosure also exhibit the same technical effect under the same circuit architecture (e.g., the lighting device 100B as shown in FIG. 5 to FIG. 7).

### BENEFICIAL EFFECTS OF THE EMBODIMENT

In conclusion, in the lighting device provided by the present disclosure, by virtue of “the five external pads being spaced apart from each other,” and “a portion of the connection component passing through the first substrate and the third substrate, so as to be electrically coupled to the configuration pads and the five external pads,” the lighting device can perform functional testing on the integrated circuit chip before being installed on the circuit substrate.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A lighting device, comprising:
a carrier including a first substrate, a second substrate, and a third substrate, wherein the second substrate is located between the first substrate and the third substrate;
a plurality of configuration pads disposed on the first substrate, wherein the configuration pads are spaced apart from each other;
a plurality of light emitting diode chips and an integrated circuit chip electrically connected to the configuration pads;
five external pads disposed on the third substrate, wherein the five external pads are spaced apart from each other; and
a connection component disposed on the second substrate, wherein a portion of the connection component passes through the first substrate and the third substrate, so as to be electrically coupled to the configuration pads and the five external pads.

2. The lighting device according to claim 1, wherein the five external pads have two anode external pads and three function external pads, a first shortest distance is between the two anode external pads, and a second shortest distance is between any one of the two anode external pads and any one of the three function external pads, and wherein the first shortest distance is less than the second shortest distance.

3. The lighting device according to claim 1, wherein the five external pads have two anode external pads and three function external pads, one of the two anode external pads is electrically coupled to a power supply voltage of the integrated circuit chip, and another one of the two anode external pads is electrically coupled to a plurality of anode terminals of the light emitting diode chips.

4. The lighting device according to claim 1, wherein the five external pads have two anode external pads and three function external pads, one of the two anode external pads is electrically coupled to a power supply voltage of the integrated circuit chip and an anode terminal of one of the light emitting diode chips, and another one of the two anode external pads is electrically coupled to a plurality of anode terminals of remaining ones of the light emitting diode chips.

5. The lighting device according to claim 3, further comprising a solder resist coating disposed on the third substrate, wherein the solder resist coating separates a plurality of configuration regions on the third substrate, and the two anode external pads are disposed in one of the configuration regions.

6. The lighting device according to claim 4, further comprising a solder resist coating disposed on the third substrate, wherein the solder resist coating separates a plurality of configuration regions on the third substrate, and the two anode external pads are disposed in one of the configuration regions.

7. The lighting device according to claim 3, wherein two of the three function external pads are respectively and electrically coupled to a data input electrode and a data output electrode of the integrated circuit chip, and another one of the three function external pads is electrically coupled to a ground.

8. The lighting device according to claim 4, wherein two of the three function external pads are respectively and electrically coupled to a data input electrode and a data output electrode of the integrated circuit chip, and another one of the three function external pads is electrically coupled to a ground.

9. The lighting device according to claim 1, wherein the configuration pads and a plurality of sides of the first substrate are spaced apart from each other.

10. The lighting device according to claim 1, wherein each of the light emitting diode chips has an anode terminal and a cathode terminal, and each of the anode terminal and the cathode terminal is electrically connected to one of the configuration pads, wherein one of the configuration pads electrically connected to the anode terminal is defined as an anode pad, and one of the configuration pads electrically connected to the cathode terminal is defined as a cathode pad, and wherein the anode pads and the cathode pads are arranged in two columns, the anode pads are arranged in a first column, and the cathode pads are arranged in a second column.

11. The lighting device according to claim 1, wherein each of light emitting diode chips has an anode terminal and a cathode terminal, and each of the anode terminal and the cathode terminal is electrically connected to the configuration pad, wherein one of the configuration pads electrically connected to the anode terminal is defined as an anode pad, and one of the configuration pads electrically connected to the cathode terminal is defined as a cathode pad, and wherein the anode pads and the cathode pads are arranged in a first column and a second column, and each of the first column and the second column has at least one of the anode pads and at least one of the cathode pads.

12. The lighting device according to claim 1, wherein a quantity of the light emitting diode chips is M, and M is a positive integer greater than or equal to three, and wherein the connection component includes:
an M+5 number of connection conduction pads disposed on the second substrate, wherein the M+5 connection conduction pads are spaced apart from each other; and
a plurality of conductive pillars penetrating the first substrate and the second substrate, wherein a subset of the conductive pillars are electrically coupled to the configuration pads and the M+5 connection conduction pads, and another subset of the conductive pillars are electrically coupled to the five external pads and the M+5 connection conductive pads.

13. The lighting device according to claim 12, wherein a total area of the M+5 connection conduction pads is greater than or equal to 50% of a total area of the second substrate.
